(19) United States
(12) Patent Application Publication
(10) Pub. No.: US 2025/0224677 A1
(43) Pub. Date: Jul. 10, 2025

(54) SELECTIVE DEPOSITION ON METAL-CONTAINING MASK USING PROMOTER

(71) Applicant: Tokyo Electron Limited, Tokyo (JP)

(72) Inventors: Katie Lutker-Lee, Albany, NY (US); Wenyi Xie, Albany, NY (US); Subhadeep Kal, Albany, NY (US)

(21) Appl. No.: 18/408,271

(22) Filed: Jan. 9, 2024

(51) Int. Cl. G03F 7/11; C23C 16/04; C23C 16/50; C23C 16/52; G03F 7/004

(52) U.S. Cl. CPC G03F 7/11; C23C 16/042; C23C 16/50; C23C 16/52; G03F 7/0042

(57) ABSTRACT

A method of selective deposition on a metal-containing mask using a promoter includes treating metal-containing mask surfaces and exposed surfaces of a metal-free underlayer with the promoter to form functionalized mask surfaces, and treating the functionalized mask surfaces and the exposed surfaces of the metal-free underlayer with a precursor to selectively deposit a material on the functionalized mask surfaces. The promoter is configured to selectively functionalize the metal-containing mask surfaces to form the functionalized mask surfaces. The promoter is further configured to promote selective deposition of the material on the functionalized mask surfaces.

### TECHNICAL FIELD

The present invention relates generally selective deposition processes, and, in particular embodiments, to systems and methods for selectively depositing a material on a metal-containing mask.

### BACKGROUND

Microelectronic device fabrication typically involves a series of manufacturing techniques that include formation, patterning, and removal of a number of layers of material on a substrate. Etch masks may be formed (e.g., deposited, grown, patterned) to protect regions of the substrate and allow for pattern transfer via etching. Wet or dry etching processes may be used, with plasma etching processes being an example of a dry etching process. Etching processes are used extensively to form a network of electronic components and interconnect elements (e.g., transistors, resistors, capacitors, metal lines, contacts, and vias) integrated in a monolithic structure (i.e., an integrated circuit).

Photolithographic processes are often utilized to form etch masks by exposing a photoresist layer formed over an underlying layer to structured actinic radiation and developing the photoresist to form a relief pattern. The relief pattern can then be transferred to the underlying layer (e.g., an etch target layer or an underlying hard mask layer formed over an etch target layer). The minimum feature size of photolithographic techniques is limited by the resolution of the optical system (e.g., because of diffraction limitations that depend on the wavelength of the actinic radiation used for the exposure).

As technology advances, feature sizes (i.e., critical dimensions) are reduced and device density increases. Since shorter wavelengths are less hindered by diffraction limitations, extreme ultraviolet (EUV) lithography has become widely used, for sub-10 nm technology nodes (e.g., 13.5 nm EUV lithography for 7 nm and 5 nm technology nodes). However, with the improved optical resolution, EUV photoresists present significant engineering challenges for meeting stringent cost and/or quality requirements. For example, chemically amplified resist (CAR) and similar polymer resists, which are commonly used in 193 nm lithography, are typically produced using liquid based spin-on techniques that consume a significant amount of complex metal cluster precursors, resulting in very high cost. CARs also tend to have low absorption coefficients at EUV wavelengths, such as 13.5 nm, and as a result, suffer from poor sensitivity.

Metal-oxide resist (MOR) may be an attractive alternative to CAR for use in EUV lithography due to its high etch resistance/selectivity and photo reactivity to EUV. Yet, challenges remain with using MOR photoresists and other photoresists typically utilized for EUV lithography. For instance, smaller dimensionality decreases feature stability and exacerbates interactions between the features of the mask, which can lead to photoresist line or pillar collapse. The account for this and other issues such as the depth of focus of the optics, low aspect ratio photoresist patterns (e.g., having a film thickness <15 nm) may be used. However, during the subsequent etch process, thinner photoresist films may be excessively damaged or etched away entirely destroying the integrity of the pattern transfer. Moreover, stochastically-driven irregularities (such as line roughness, resist height thinning, line thinning, line edge roughness (LER), line width roughness (LWR), resist wiggling, etc.) are amplified by the reduced size and increased density of the features.

Selective deposition processes (also referred to as area selective deposition (ASD) processes) can be used to selectively deposit (i.e., grow) a material on desired surfaces (e.g., a patterned mask surface) while depositing less of the material (or even none of the material) on other surfaces (e.g., exposed underlying materials). Selective deposition can be difficult, such as when the material being deposited interacts similarly with both the desired surfaces and the undesired surfaces. Even worse, some systems exhibit reverse selectivity to certain materials (e.g., the material selectively deposits on the undesired surfaces relative to the desired surfaces). For these situations, additional methods are necessary to achieve selective deposition.

Selective deposition processes have been used to mitigate problems associated with reduced mask material (such as those mentioned above) in CAR photoresist systems. Unfortunately, the common methods and chemistries that have been used to selectively deposit on CAR photoresists are not selective to metal-containing resists (e.g., metal-based resists such as MOR). Therefore, improved methods of selectively depositing materials capable of selectively depositing a wide variety of materials on metal-containing resists may be desirable.

### SUMMARY

In accordance with an embodiment of the invention, a method includes treating metal-containing mask surfaces and exposed surfaces of a metal-free underlayer with a promoter to form functionalized mask surfaces, and treating the functionalized mask surfaces and the exposed surfaces of the metal-free underlayer with a precursor to selectively deposit a material on the functionalized mask surfaces. The promoter is configured to selectively functionalize the metal-containing mask surfaces to form the functionalized mask surfaces. The promoter is further configured to promote selective deposition of the material on the functionalized mask surfaces.

In accordance with another embodiment of the invention, a method includes adsorbing a ligand at metal sites of a patterned metal-containing photoresist to form functionalized photoresist surfaces including the ligand. The adsorbing of the ligand includes exposing both the patterned metal-containing photoresist and a metal-free underlayer to the ligand. The method further includes selectively depositing a material on the functionalized photoresist surfaces by exposing the functionalized photoresist surfaces and the metal-free underlayer to a precursor.

In accordance with still another embodiment of the invention, a system includes a process chamber, a substrate support disposed in the process chamber, a promoter source fluidically coupled to the process chamber and configured to provide a promoter through a first valve, a precursor source fluidically coupled to the process chamber and configured to provide a precursor through a second valve, and a controller operationally coupled to the first valve and the second valve. The substrate support is configured to support a substrate that includes metal-containing mask surfaces and exposed surfaces of a metal-free underlayer. The controller includes a processor and a non-transitory computer-readable medium storing a program including instructions that, when executed by the processor, perform a method that includes treating the metal-containing mask surfaces and the exposed surfaces of the metal-free underlayer with the promoter to form functionalized mask surfaces, and treating the functionalized mask surfaces and the exposed surfaces of the metal-free underlayer with the precursor to selectively deposit a material on the functionalized mask surfaces. The promoter is configured to selectively functionalize the metal-containing mask surfaces to form the functionalized mask surfaces. The promoter is further configured to promote selective deposition of the material on the functionalized mask surfaces.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates an example selective deposition process that includes a promoter treatment step to selectively functionalize metal-containing mask surfaces in the presence of exposed surfaces of an underlayer, and a selective deposition step to selectively deposit a material on the functionalized mask surfaces in accordance with embodiments of the invention;

FIG. 2 illustrates an example selective deposition process that includes a promoter treatment step and a selective deposition step, where a ligand is adsorbed at metal site of a metal-containing photoresist during the promoter treatment in accordance with embodiments of the invention;

FIG. 3 illustrates an example selective deposition process that includes a promoter treatment step and a selective deposition step, where the promoter is implemented as an acetylacetone (ACAC) species in accordance with embodiments of the invention;

FIG. 4 illustrates an example selective deposition process that includes a promoter treatment step and a selective deposition step, where the promoter is hexafluoroacetylacetone (HFAC), the precursor is tetrafluorosilane (SiF₄), and the deposited material is silicon-based in accordance with embodiments of the invention;

FIG. 5 illustrates an example selective deposition process that includes a promoter treatment step and a selective deposition step, where the promoter is an ACAC species including an aliphatic group, the precursor is methane (CH₄), and the deposited material is carbon-based in accordance with embodiments of the invention;

FIG. 6 illustrates an example deposition system that includes a deposition apparatus having a process chamber within which selective deposition processes including a promoter treatment step and a selective deposition step may be performed in accordance with embodiments of the invention;

FIG. 7 illustrates an example method of selectively depositing a material on surfaces of a metal-containing mask in the presence of exposed surfaces of a metal-free underlayer in accordance with embodiments of the invention; and

FIG. 8 illustrates an example method of selectively depositing a material on surfaces of a patterned metal-containing photoresist in the presence of exposed surfaces of a metal-free underlayer in accordance with embodiments of the invention.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope. Unless specified otherwise, the expressions “around”, “approximately”, and “substantially” signify within 10%, and preferably within 5% of the given value or, such as in the case of substantially zero, less than 10% and preferably less than 5% of a comparable quantity.

With high-NA (numerical aperture) EUV lithography on the horizon, resist thickness continues to shrink and problems with stochastically driven roughness become more detrimental. These problems are transferred to underlying layers during the etching process, leading to problems with etch profile and uniformity, ultimately reducing yield, or in some cases rendering the processes completely intractable. Shrinking resist thickness may also cause issues that require high-selectivity etches.

At the stage that these problems manifest, the mask has already been formed so that an underlayer is exposed through openings in the mask. For this reason, selective deposition is potentially attractive for mitigating these issues without adversely affecting the process of transferring the pattern to the underlayer. For example, materials selectively deposited on the mask surfaces may “heal” (e.g., smooth, fix breaks) defects in the mask pattern while depositing little or no material on the underlayer. However, direct selective deposition on metal-containing resists is not possible for the vast majority of deposition materials. Further, conventional chemistries and methods capable of facilitating selective deposition of various deposition materials on organic resists (such as CAR organic resists) do not provide the selective effect when applied to metal containing resists.

In accordance with embodiments herein described, the invention proposes a selective deposition process that selectively deposits a material on metal-containing mask surfaces in the presence of exposed surfaces of a metal-free underlayer using a promoter to selectively functionalize the metal-containing mask surfaces. The promoter is a species (e.g., small molecule) configured to selectively functionalize metal-containing mask surfaces to form the functionalized mask surfaces as well as to promote selective deposition of a material (e.g., a silicon-based material, carbon-based, material, etc.) on the functionalized mask surfaces.

Specifically, the selective deposition process includes two steps: a promoter treatment step and a selective deposition step. During the promoter treatment step, the metal-containing mask surfaces (e.g., surfaces of a patterned resist layer, such as a patterned metal oxide photoresist, including, for example, tin oxide, and the like) and exposed surfaces of a metal-free underlayer (e.g., a dielectric layer such as an oxide layer, an organic layer, such as a bottom antireflective coating (BARC), and others) are treated with a promoter (e.g., a ligand, such as a chelating molecule like an acetylacetone (ACAC) species, an ether, and others) to form functionalized mask surfaces.

The functionalized mask surfaces and the exposed surfaces of the metal-free underlayer are then treated with a precursor (e.g., a deposition gas, which may be a mixture of gases including one or more precursor species) during the selective deposition step to selectively deposit the material on the functionalized mask surfaces. The functionalized mask surfaces may include promoter molecules that have adsorbed to the metal-containing mask surfaces at metal sites. For example, the promoter molecules may include metal-bonding sites and functional groups. The metal-bonding sites may interact with metal sites (e.g. chemisorption, physisorption, chemical bonding, etc.) to selectively functionalize the metal-containing mask surfaces while the functional groups (e.g., outwardly facing) may interact with the precursor (e.g., react with, attract, favorably redistribute electronic structure, lower a reaction barrier) to promote the selective deposition of the material.

By using a promoter molecule that adsorbs to (reacts with, as in chemisorption or adheres to, as in physisorption) the metal-containing mask surfaces, the surfaces may be selectively functionalized in such a manner that the deposition chemistry of the material being deposited becomes selective to the metal-containing mask over exposed surfaces of the metal-free underlayer. That is, the material may advantageously favor growing on the functionalize mask surfaces over the non-functionalized surfaces of the metal-free underlayer.

Various potential benefits may be achieved by enabling selective deposition on metal-containing masks. For example, such metal-containing masks can be used for EUV lithography, including as high-NA EUV resists. Selective deposition on metal-containing resists may advantageously help with mask budget in addition to possibly addressing roughness concerns during pattern transfer. The selective deposition on metal-containing resists may also facilitate improved process transfer for smaller features by smoothing mask features. That is, the selectively deposited material may mitigate stochastically-driven irregularities, such as line roughness, resist height thinning, line thinning, LER, LWR, resist wiggling, line breaks, and others.

The selective deposition processes described herein, may be performed in a deposition system, such as a plasma deposition system. Additionally, the deposition processes may have the advantage of being capable of integration into current process flows, such as etch processes. For example, the selective deposition processes may advantageously be performed in situ in an etching system, such as a plasma etching system.

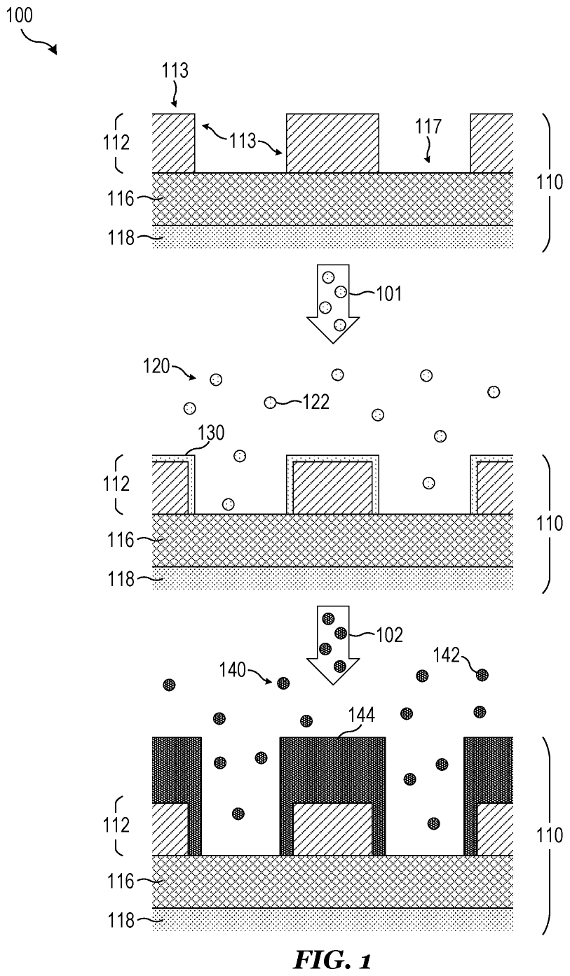

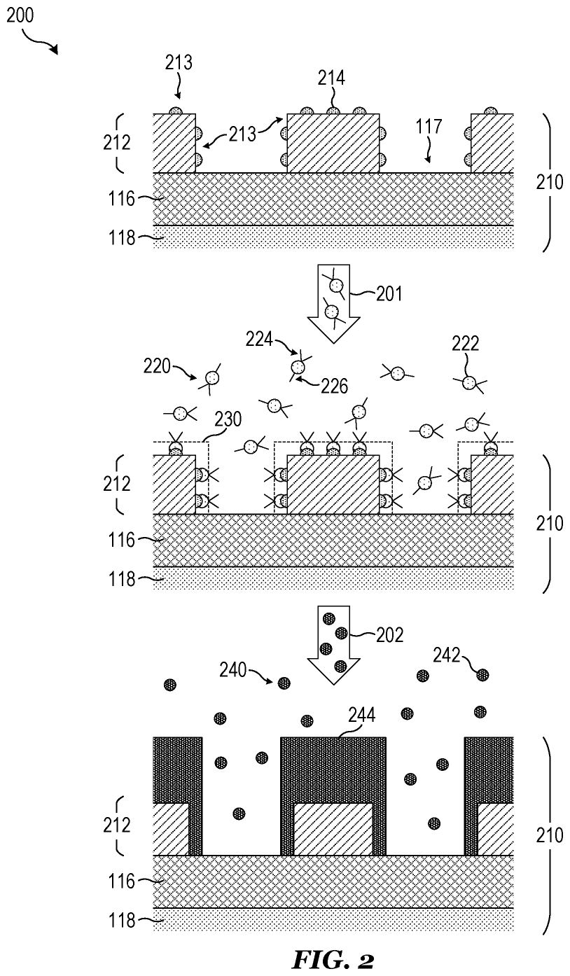

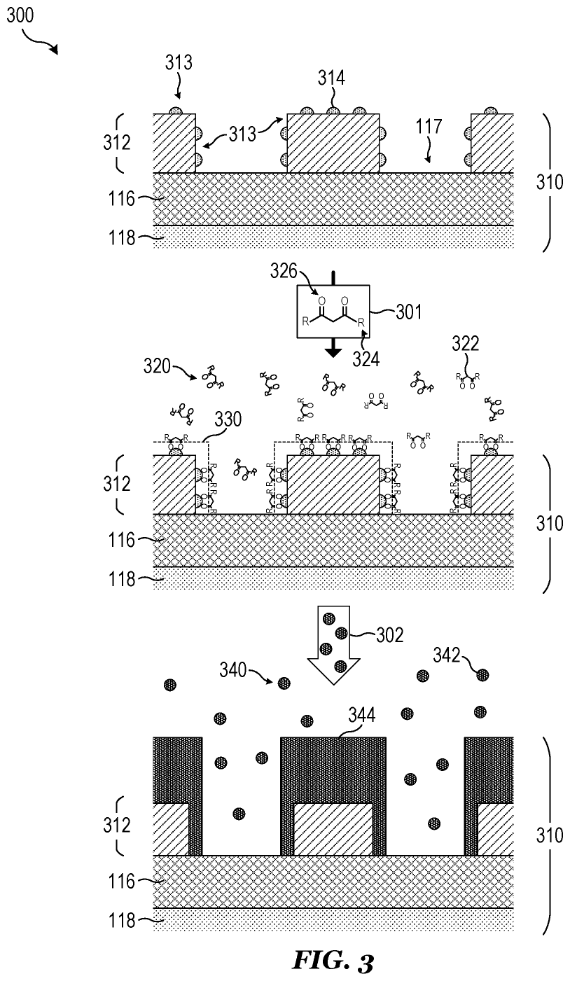

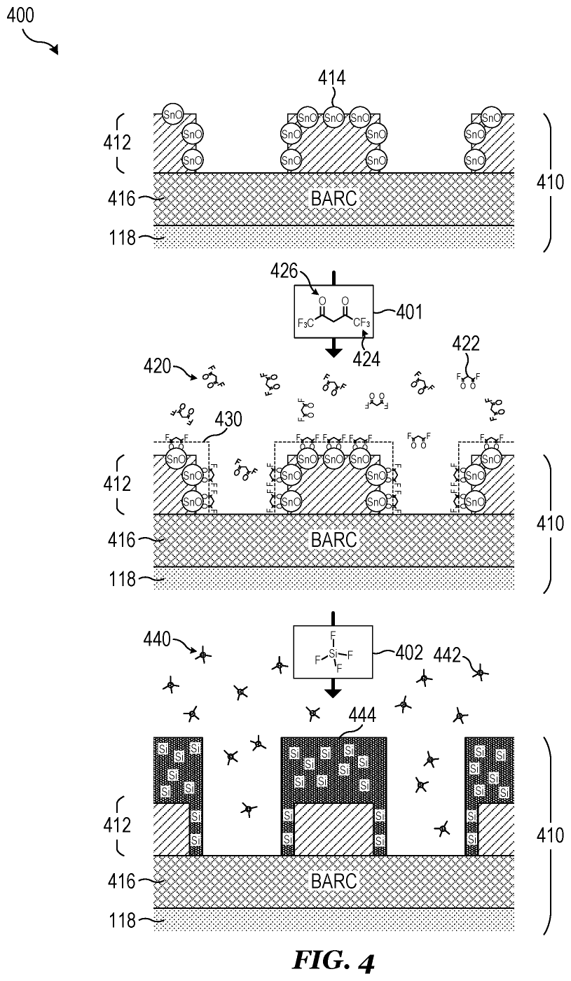

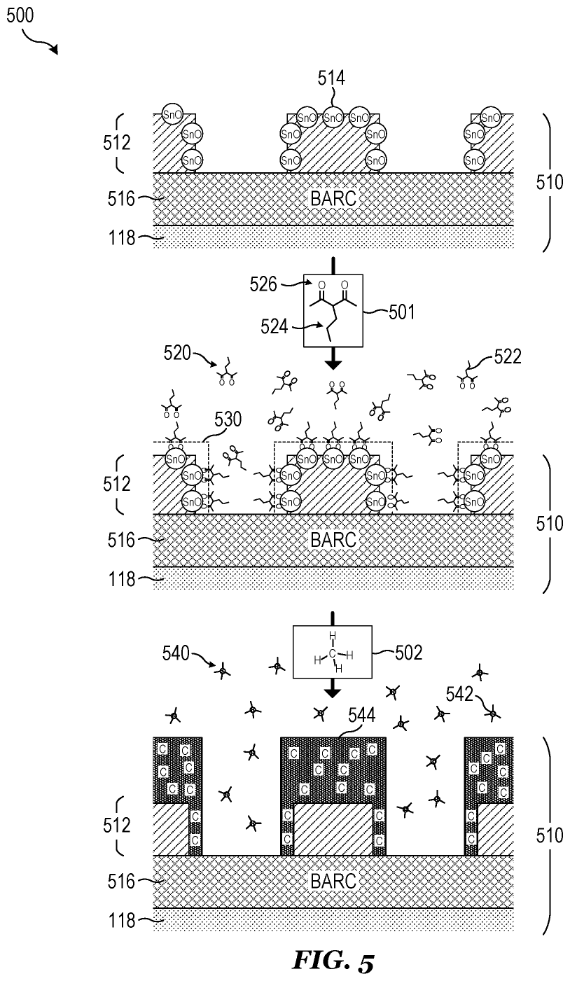

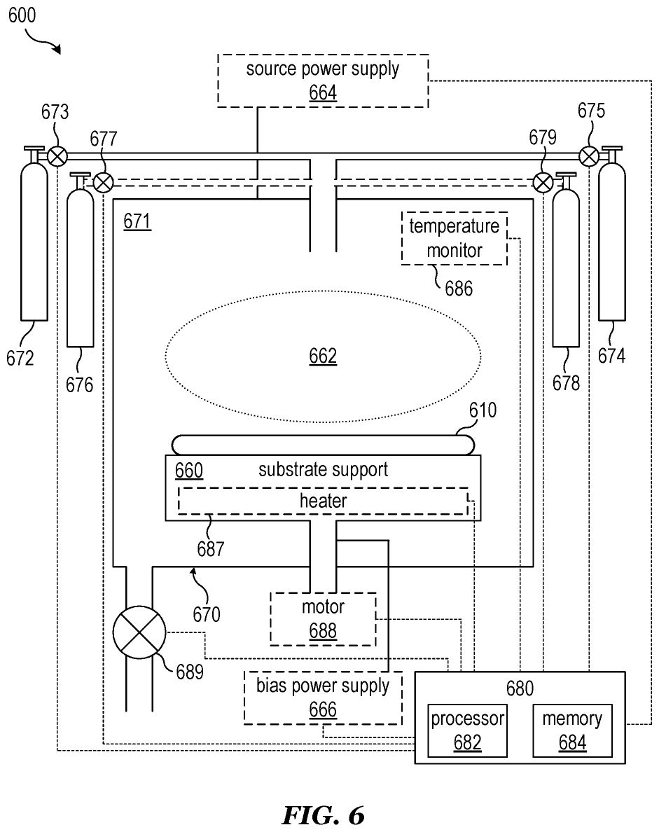

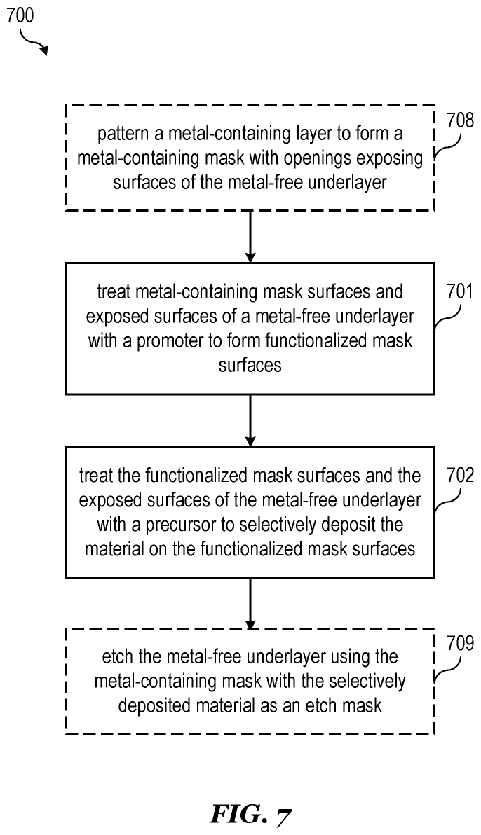

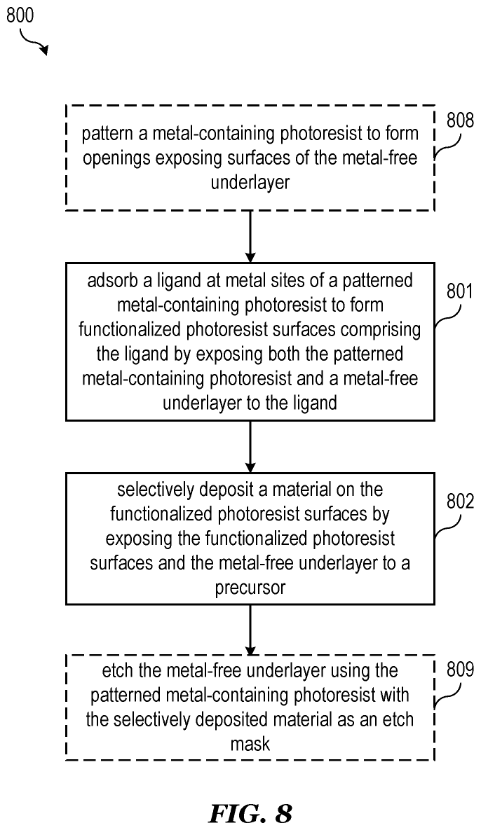

Embodiments provided below describe various systems and methods for selective deposition processes, and in particular, to systems and methods for selectively depositing a material on a metal-containing mask using a promoter. The following description describes the embodiments. FIG. 1 is used to describe an example selective deposition process including a promoter treatment step and a selective deposition step. Two more example selective deposition processes which may be considered specific implementations of the general selective deposition process of FIG. 1 are described using FIGS. 2 and 3. Two specific examples of selective deposition process are described using FIGS. 4 and 5. An example deposition system that can be used to perform the methods is described using FIG. 6. Two example methods of selectively depositing a material are described using FIGS. 7 and 8.

FIG. 1 illustrates an example selective deposition process that includes a promoter treatment step to selectively functionalize metal-containing mask surfaces in the presence of exposed surfaces of an underlayer, and a selective deposition step to selectively deposit a material on the functionalized mask surfaces in accordance with embodiments of the invention.

Referring to FIG. 1, a selective deposition process 100 begins with a substrate 110 that includes a metal-containing mask 112 overlying a metal-free underlayer 116. The metal-containing mask 112 has been formed such that it has metal-containing mask surfaces 113 and various openings revealing exposed surfaces 117 of the metal-free underlayer 116 below. The metal-free underlayer 116 may be any suitable material (e.g., a BARC) that does not include metal, specifically metal near the exposed surfaces 117. Of course, the substrate 110 may (and very often does) include various other layers below the metal-free underlayer 116, schematically represented by additional layers 118.

The metal-containing mask surfaces 113 and the exposed surfaces 117 of the metal-free underlayer 116 are both treated with a promoter 120 to form functionalized mask surfaces 130 during a promoter treatment step 101 of the selective deposition process 100. For example, the promoter 120 may include a small molecule 122 to which the metal-containing mask surfaces 113 and the exposed surfaces 117 are exposed. The promoter 120 is configured to selectively functionalize the metal-containing mask surfaces 113 (and not functionalize the exposed surfaces 117, or at least substantially not functionalize, such as only inadvertently remaining at the exposed surfaces 117 with little or no interaction).

The metal-containing mask 112 may be formed by patterning a metal-containing resist such as a MOR photoresist. In one embodiment, the metal-containing mask 112 is a tin oxide-based mask formed by patterning a tin oxide-based photoresist (e.g., using EUV lithography). Metal contained in the metal-containing mask 112 is present at the metal-containing mask surfaces 113, and interacts with the promoter 120 to selectively functionalize the metal-containing mask 112 and form the functionalized mask surfaces 130. There is no requirement that the promoter 120 interact in a specific way with the metal-containing mask 112, as long as the interaction is selective and it functionalizes the metal-containing mask surfaces 113 so that the selective deposition step 102 is also selective to the metal-containing mask surfaces 113. In various embodiments, the promoter 120 is adsorbed onto the metal-containing mask surfaces 113, and the promoter 120 is chemisorbed on the metal-containing mask surfaces 113 (e.g., via chemical reactions) in one embodiment, and physisorbed (e.g., via van der Waals interactions) in one embodiment. Of course, more than one interaction may take place between a given promoter and a metal-containing mask surface.

The promoter 120 may include a small molecule 122 that is configured to interact with (e.g., adsorb to) metal-containing mask surfaces. In various embodiments, the small molecule 122 is a ligand (i.e., a molecule that is configured to form coordinated bonds with a metal atom, such as with available d-orbitals). In some embodiments the small molecule is a chelating molecule (a ligand that is configured to form multiple coordinated bonds with a single metal atom). Some examples of molecules that may be used as the small molecule 122 in the promoter 120 are ACAC species (e.g., molecule with a similar structure to an ACAC molecule, but where one or more atoms is replaced with a different component) and ethers. In one embodiment, the small molecule 122 is HFAC. In another embodiment, the small molecule 122 is a crown ether. In still another embodiment, the small molecule 122 is ethylenediaminetetraacetic acid (EDTA).

In a selective deposition step 102 of the selective deposition process 100, functionalized mask surfaces 130 and the exposed surfaces 117 of the metal-free underlayer 116 are treated with a deposition gas 140 that includes a precursor 142 to selectively deposit a deposition material 144 on the functionalized mask surfaces 130 (and therefore on the metal-containing mask surfaces 113 by virtue of the selective functionalization by the promoter 120). At this time, may be worth noting that the promoter 120 acts in an opposite manner as an inhibitor (which can also be used in theory to facilitate selective deposition). However, in contrast to an inhibitor, the promoter 120 has the advantage of avoiding modification (i.e. functionalization) of the metal-free underlayer 116 which in turn may prevent damage to the metal-free underlayer 116 and also prevent future problems with etching the metal-free underlayer 116.

Selective deposition using the deposition gas 140 can be achieved using a wide variety of deposition techniques, such as chemical vapor deposition (CVD), atomic layer deposition (ALD) and molecular layer deposition (MLD). The deposition gas 140 may be in the vapor phase or a plasma may be formed during the deposition (such as in plasma enhanced CVD (PE-CVD)). Some deposition techniques also use surface modification techniques. However, these surface modification techniques differ in various ways from the use of the promoter 120 described here. For example, many conventional surface modification techniques form covalent bonds with both a growth surface and a growth layer deposited on the growth surface. Both the surface modification and the growth layer are often self-limiting (as in ALD and MLD) requiring many cycles to grow a small amount of material, (which is in contrast to the selective deposition process 100 being described here that may only use two steps and can deposit multiple layers of the deposition material 144 on the metal-containing mask 112, as illustrated). Additionally, as already mentioned, conventional surface modification methods do not use chemistry that results in selective deposition on metal-containing masks.

The deposition material 144 may be any desired material as long as it is selected so that the functionalized mask surfaces 130 promote the growth of the deposition material 144 on the functionalized mask surfaces 130 (relative to the exposed surfaces 117). In various embodiments, the deposition material 144 is a silicon-based material. In other embodiments, the deposition material 144 is a carbon-based material. Of course, many materials suitable for use as the deposition material 144 may be combinations of many elements, and may include both silicon and carbon. Other possible materials include oxides, carboxides, boron-based materials, and others.

In order to deposit the various materials as the deposition material 144, many different species may be used as the precursor 142 (including combinations of different species). By way of example, silicon-based deposition materials may be selectively deposited using silane (SiH₄), a halosilane, such as tetrafluorosilane (SiF₄), tetrachlorosilane (SiCl₄), or another silicon-containing precursor as the precursor 142. For carbon-based deposition materials, the precursor 142 may be methane (CH₄), carbon monoxide (CO), a higher order hydrocarbon (CₓH_{y} with x>1), a fluorocarbon, hydrofluorocarbon, as well as other halogenated hydrocarbons, and other carbon-containing precursors. Halogens may be combined with many materials and used as precursors, such as using boron trichloride (BCl₃) to deposit boron-based materials.

Additional gases may be included along with precursor 142 (or precursors) in the deposition gas 140. For example, the deposition gas 140 may include one or more carrier gases, stabilizing gases, supporting gases, and others. For example, a noble gas such as argon may be included as a carrier gas. Relatively inert gases such as nitrogen may also be used as a carrier gas (or for another purpose). Reactive gases may also be included, such as hydrogen or oxygen. Indeed, as long as the deposition gas 140 along with the precursor 142 selectively deposits on the functionalized mask surfaces 130, any desired gas may be included, as may be apparent to those of skill in the art.

The additional layers 118 may include various layers ranging from amorphous silicon (aSi) to organic layers (e.g., an OPL) to oxides (e.g., silicon dioxide (SiO₂) such as LTO, tetraethyl orthosilicate (TEOS), aluminum oxide (Al₂O₃), etc.) to nitrides (e.g., silicon nitride (Si₃N₄)) and even to metals (as long as the metal-free underlayer 116 is sufficiently thick to prevent metal from reaching the exposed surfaces 117). Moreover, the substrate 110 may be any suitable substrate, such as an insulating, conducting, or semiconducting substrate with one or more layers disposed thereon. For example, the substrate 110 may be a semiconductor wafer, such as a silicon wafer, and include various layers, structures, and devices (e.g., forming integrated circuits). In one embodiment, the substrate 110 includes silicon. In another embodiment, the substrate 110 includes silicon germanium (SiGe). In still another embodiment, the substrate 110 includes gallium arsenide (GaAs). Of course, many other suitable materials, semiconductor or otherwise, may be included in the substrate 110 as may be apparent to those of skill in the art.

FIG. 2 illustrates an example selective deposition process that includes a promoter treatment step and a selective deposition step, where a ligand is adsorbed at metal site of a metal-containing photoresist during the promoter treatment in accordance with embodiments of the invention. The selective deposition process of FIG. 2 may be a specific implementation of other selective deposition processes described herein such as the selective deposition process of FIG. 1, for example. Similarly labeled elements may be as previously described.

Referring to FIG. 2, a selective deposition process 200 includes a substrate 210 with a metal-containing mask 212 that includes metal sites 214 (e.g., metal atoms at or near the surface, which may be single metal atoms or considered as such depending on the density of metal species in the metal-containing mask 212) at or near metal-containing mask surfaces 213. It should be noted that here and in the following a convention has been adopted for brevity and clarity wherein elements adhering to the pattern [x10] where ‘x’ is the figure number may be related implementations of a substrate in various embodiments. For example, the substrate 210 may be similar to the substrate 110 except as otherwise stated. An analogous convention has also been adopted for other elements as made clear by the use of similar terms in conjunction with the aforementioned numbering system.

The selective deposition process 200 is similar to the selective deposition process 100 except that the selective deposition process 200 schematically illustrates an example mechanism for selectively functionalizing the metal-containing mask surfaces 213 during a promoter treatment step 201 to form functionalized mask surfaces 230 that facilitate selective deposition of a deposition material 244 during a selective deposition step 202. For example, during the promoter treatment step 201, the metal-containing mask surfaces 213 and the exposed surfaces 117 of the metal-free underlayer 116 are exposed to a promoter 220 that includes a ligand 222 with a functional group 224 (e.g., a halogen-containing group, aliphatic group, etc.) and a metal-bonding group 226 (e.g., oxygen, nitrogen, etc.). The metal-bonding group 226 is configured to interact with metal sites 214 (e.g. chemisorption, physisorption, etc.) and adsorb at the metal sites 214 to selectively functionalize the metal-containing mask surfaces 213. Meanwhile, the functional group 224 is configured to interact with a precursor 242 of a deposition gas 240 to promote selective deposition of the deposition material 244 on the functionalized mask surfaces 230.

FIG. 3 illustrates an example selective deposition process that includes a promoter treatment step and a selective deposition step, where the promoter is implemented as an ACAC species in accordance with embodiments of the invention. The selective deposition process of FIG. 3 may be a specific implementation of other selective deposition processes described herein such as the selective deposition process of FIG. 2, for example. Similarly labeled elements may be as previously described.

Referring to FIG. 3, a selective deposition process 300 includes a substrate 310 with a metal oxide-based mask 312 that includes metal sites 314 at or near metal-containing mask surfaces 313. In this example, the metal oxide-based mask 312 specifically includes a metal oxide (such as tin oxide, for example). A specific implementation of a promoter treatment step 301 includes treating the metal-containing mask surfaces 313 and exposed surfaces 117 of a metal-free underlayer 116 with a promoter 320 that includes an ACAC species 322 to form functionalized mask surfaces 330 (e.g., through ligand adsorption, as shown here). The functionalized mask surfaces 330 (and of course the exposed surfaces 117 of the metal-free underlayer 116) are then treated with a deposition gas 340 that includes a precursor 342 to form a deposition material 344 on the functionalized mask surfaces 330 in a selective deposition step 302.

The ACAC species 322 may be any molecule that has a similar structure to an ACAC molecule where any carbon atom, hydrogen atom, or oxygen atom may be replaced with a different component. One such substituted ACAC species structure is schematically illustrated as having a functional group 324 (shown as two R groups, which may simply be methyl groups (CH₃—) as in an ACAC molecule or may be replaced with other groups, such as trifluoromethyl groups (CF₃—), for example) and a metal-bonding group 326 (here, the oxygen atoms of the ACAC molecule, but one or both oxygens could be substituted for a nitrogen-containing group, such as to form a NacNac species, a subclass of ACAC species). Of course, there is no requirement that there be two functional groups, that they be in those locations on the ACAC molecule, or that included functional groups be the same.

FIG. 4 illustrates an example selective deposition process that includes a promoter treatment step and a selective deposition step, where the promoter is hexafluoroacetylacetone (HFAC), the precursor is tetrafluorosilane (SiF₄), and the deposited material is silicon-based in accordance with embodiments of the invention. The selective deposition process of FIG. 4 may be a specific implementation of other selective deposition processes described herein such as the selective deposition process of FIG. 3, for example. Similarly labeled elements may be as previously described.

Referring to FIG. 4, a selective deposition process 400 includes a substrate 410 with a tin oxide-based mask 412 that includes tin sites 414. In this example, the tin oxide-based mask 412 specifically includes a metal oxide (such as tin oxide, for example) and is formed over a BARC 416 (a metal-free underlayer). A specific implementation of a promoter treatment step 401 utilizes a promoter 420 that includes HFAC 422 (a ligand that is an ACAC species and has a halogen-containing group 424 and a metal-bonding group 426) to form HFAC-functionalized mask surfaces 430. In a specific implementation of a selective deposition step 402, the HFAC-functionalized mask surfaces 430 are treated with a deposition gas 440 that includes tetrafluorosilane 442 (SiF₄, acting as a precursor) to form silicon-based material 444 on the HFAC-functionalized mask surfaces 430.

Using HFAC 422 in combination with tetrafluorosilane 442 to form the silicon-based material 444 is a specific example of using a promoter and a deposition gas that both include the same halogen (here, fluorine, but may also be chlorine, etc.). However, while there may be some advantages to this arrangement in certain applications, it is by no means required. For example, in some cases the halogens may be different, the primary component of the selectively deposited material may be different, or fewer or no halogens may be included (one example of which is discussed in FIG. 5).

FIG. 5 illustrates an example selective deposition process that includes a promoter treatment step and a selective deposition step, where the promoter is an ACAC species including an aliphatic group, the precursor is methane (CH₄), and the deposited material is carbon-based in accordance with embodiments of the invention. The selective deposition process of FIG. 5 may be a specific implementation of other selective deposition processes described herein such as the selective deposition process of FIG. 3, for example. Similarly labeled elements may be as previously described.

Referring to FIG. 5, a selective deposition process 500 includes a substrate 510 with a tin oxide-based mask 512 that includes tin sites 514. In this example (and the last example), the tin oxide-based mask 512 specifically includes a metal oxide (such as tin oxide, for example) and is formed over a BARC 516 (a metal-free underlayer). Here, a specific implementation of a promoter treatment step 501 utilizes a promoter 520 that includes an ACAC species 522 with an aliphatic group 524 (acting as a functional group) and a metal-bonding group 526 to form aliphatic-functionalized mask surfaces 530. Further, in the specific implementation of a selective deposition step 502, the aliphatic-functionalized mask surfaces 530 are treated with a deposition gas 540 that includes methane 542 (CH₄, acting as a precursor) to form a carbon-based material 544 on the aliphatic-functionalized mask surfaces 530.

Using a promoter 520 with the aliphatic group 524 in combination with methane 542 to form the carbon-based material 544 is a specific example of using a promoter with an aliphatic group (here, a butyl chain, but any aliphatic group including branching chains and unsaturated chains may be used) to selectively deposit a carbon-based material. As before, while there may be some advantages to this arrangement in certain applications, it is by no means required. For example, in some cases carbon-based materials may be selectively deposited without using aliphatic functional groups, or aliphatic groups may be used to selectively deposit other materials.

FIG. 6 illustrates an example deposition system that includes a deposition apparatus having a process chamber within which selective deposition processes including a promoter treatment step and a selective deposition step may be performed in accordance with embodiments of the invention. The deposition system of FIG. 6 may be used to perform any of the example selective deposition processes described herein such as the selective deposition process of FIG. 1, for example. Similarly labeled elements may be as previously described.

Referring to FIG. 6, a deposition system 600 (e.g., a plasma deposition system, and may also be an etching system, such as a plasma etching system like an RIE etching system) includes a substrate support 660 disposed within a process chamber 671 of a deposition apparatus 670, such as a plasma deposition chamber, and configured to support a substrate 610. A promoter source 672 (e.g., a gas source or sources including a promoter molecule such as a ligand) and a precursor source 674 (e.g., a gas source or sources including one or more precursors having components to be selectively deposited on a metal-containing mask) are fluidically coupled to the process chamber 671 through a promoter valve 673 and a precursor valve 675 respectively. Additional gas sources and valves may also be included in the deposition system 600. For example, an optional additional gas source 676 may be fluidically coupled to the process chamber 671 through an optional additional gas valve 677 (an additional gas may be any type of gas, and multiple additional gases may be included) while an optional carrier gas source 678 may be fluidically coupled to the process chamber 671 through an optional carrier gas valve 679. An exhaust valve 689 is included to evacuate the process chamber 671 during the deposition process.

The deposition system 600 may be configured to generate an optional plasma 662 during any or all of the steps of a deposition process (e.g., during a promoter treatment step, a selective deposition step, a plasma etching process, such as an RIE process, etc.). For example, an optional source power supply 664 may be included that is configured to couple source power to the etching chamber 671 in order to generate the optional plasma 662. Additionally, an optional bias power supply 666 may also be included that is configured to supply bias power to the substrate support 660 (and the substrate 610). The process chamber 671 may be any suitable process chamber, such as a CVD chamber, ALD chamber, MLD, chamber, and others. Of course, when the deposition system is also a plasma etching system, the process chamber 671 may be any type of plasma etching chamber, such as a capacitively couple plasma (CCP) etching chamber, an inductively coupled plasma (ICP) etching, chamber, etc.

An optional temperature monitor 686 may be included to monitor and/or aid in controlling the temperature of the substrate 610 and the environment in the process chamber 671. An optional heater 687 may be included to elevate the temperature of the substrate 610 above the equilibrium temperature at the substrate 610 during the deposition process. Alternatively, the optional heater 687 may be a cooler to decrease the temperature of the substrate 610 below equilibrium. An optional motor 688 may also be included to improve deposition uniformity.

A controller 680 is operationally coupled to the valves (the promoter valve 673, the precursor valve 675, the optional additional gas valve 677, the optional carrier gas valve 679, etc.), and may be operationally coupled to any of the optional temperature monitor 686, the optional heater 687, the optional motor 688, and the exhaust valve 689. The controller 680 includes a processor 682 and a memory 684 (i.e., a non-transitory computer-readable medium) that stores a program including instructions that, when executed by the processor 682, perform a selective deposition process. For example, the memory 684 may have volatile memory (e.g., random access memory (RAM)) and non-volatile memory (e.g., flash memory). Alternatively, the program may be stored in physical memory at a remote location, such as in cloud storage. The processor 682 may be any suitable processor, such as the processor of a microcontroller, a general-purpose processor (such as a central processing unit (CPU), a microprocessor, a field-programmable gate array (FPGA), an application-specific integrated circuit (ASIC), and others.

FIG. 7 illustrates an example method of selectively depositing a material on surfaces of a metal-containing mask in the presence of exposed surfaces of a metal-free underlayer in accordance with embodiments of the invention. The method of FIG. 7 may be combined with other methods and performed using the systems and apparatuses as described herein. For example, the method of FIG. 7 may be combined with any of the embodiments of FIGS. 1-6 and 8. Although shown in a logical order, the arrangement and numbering of the steps of FIG. 7 are not intended to be limited. The method steps of FIG. 7 may be performed in any suitable order or concurrently with one another as may be apparent to a person of skill in the art.

Referring to FIG. 7, a method 700 of selectively depositing a material on surfaces of a metal-containing mask in the presence of exposed surfaces of a metal-free underlayer includes a step 701 of treating metal-containing mask surfaces and exposed surfaces of the metal-free underlayer with a promoter (e.g., a small molecule, such as a ligand) to form functionalized mask surfaces. The functionalized mask surfaces and the exposed surfaces of the metal-free underlayer are then treated with a precursor to selectively deposit the material (e.g., a silicon-based material, a carbon-based material, and others) on the functionalized mask surfaces in a step 702. The promoter is configured to selectively functionalize the metal-containing mask surfaces to form the functionalized mask surfaces as well as to promote selective deposition of a material on the functionalized mask surfaces.

For example, the promoter may be a ligand configured to adsorb at metal sites of the metal-containing mask surfaces and that includes a functional group configured to interact with the precursor to promote the selective deposition of the material. Various types of ligands may be used as promoters, such as ACAC species (e.g., HFAC), ethers, (e.g., crown ethers), EDTA, and others. In some embodiments, the promoter is a chelating molecule configured to form multiple bonds with a single metal atom. The functional group take various forms. One class of functional group may include a halogen (e.g., fluorine, chlorine, etc.), in which case the precursor may also include the halogen (although this is not required). Another class of functional group may include an aliphatic group (e.g., a long chain aliphatic group). In some cases, a promoter that includes an aliphatic group may be pair with a precursor that includes carbon (e.g., to selectively deposit a carbon-based material).

The method 700 may be part of a fabrication process flow in which the metal-containing mask is formed prior to step 701. For example, a metal-containing layer (e.g., a metal-oxide photoresist, such as including tin oxide, for example) may be patterned to form the metal-containing mask (e.g., patterned to form openings that expose surfaces of the metal-free underlayer) in an optional patterning step 708. Alternatively, the optional patterning step 708 may not be part of the method 700, such as when a substrate including the metal-containing mask surfaces and the metal-free underlayer has already been fabricated.

After the material is selectively deposited in step 702, the metal-free underlayer may be etched using the metal-containing mask with the selectively deposited material as an etch mask in an optional etching step 709. One example of when the optional etching step 709 may be included as part of the method 700 is when the selective deposition process including step 701 and step 702 are performed in situ in an etching chamber as part of an etching process. However, as with the optional patterning step 708, there is no requirement for the etching take place as part of the method 700 (or even at all), since the method 700 stands alone as a selective deposition method separate from how the material selectively deposited on the metal-containing mask surfaces is used after the fact.

FIG. 8 illustrates an example method of selectively depositing a material on surfaces of a patterned metal-containing photoresist in the presence of exposed surfaces of a metal-free underlayer in accordance with embodiments of the invention. The method of FIG. 8 may be combined with other methods and performed using the systems and apparatuses as described herein. For example, the method of FIG. 8 may be combined with any of the embodiments of FIGS. 1-7. Although shown in a logical order, the arrangement and numbering of the steps of FIG. 8 are not intended to be limited. The method steps of FIG. 8 may be performed in any suitable order or concurrently with one another as may be apparent to a person of skill in the art.

Referring to FIG. 8, a method 800 of selectively depositing a material on surfaces of a metal-containing mask (here implemented as a patterned metal-containing photoresist) in the presence of exposed surfaces of a metal-free underlayer includes a step 801 of adsorbing a ligand (acting as a promoter) at metal sites of the patterned metal-containing photoresist to form functionalized photoresist surfaces comprising the ligand by exposing both the patterned metal-containing photoresist and a metal-free underlayer to the ligand. The material is then selectively deposited on the functionalized photoresist surfaces in a step 802 by exposing the functionalized photoresist surfaces and the metal-free underlayer to a precursor.

As discussed elsewhere, the ligand may include a functional group and a metal-bonding group (e.g., a group with oxygen or nitrogen). The functional group may be configured to interact with the precursor to promote selective deposition of the material on the functionalized photoresist surfaces. The functional group may include various components, such as a halogen. In some embodiments, the functional group includes fluorine, such as when the precursor also includes fluorine and the selectively deposited material is a silicon-based material. One specific example of such an implementation is when the ligand is HFAC, the functional group is a trifluoromethyl group (CF₃—), and the precursor is tetrafluorosilane (SiF₄). Another possible category of functional group is an aliphatic group such as chains of hydrocarbons. For example, the functional group may include an aliphatic group when the precursor includes carbon and the selectively deposited material is a carbon-based material.

As before, various types of ligands may be used, with the broad class being ligands (molecules that form coordinated bonds with metals, e.g., d-orbitals) and a subclass being chelating molecules that form multiple bonds with a single metal atom. Some possible ligands include ACAC species (e.g., HFAC), ethers, (e.g., crown ethers), EDTA, and others.

Similar to the method 700, the method 800 may also be part of a fabrication process flow and may include one, neither, or both of an optional patterning step 808 during which a metal-containing photoresist (e.g., a metal-oxide photoresist, such as including tin oxide, for example) is patterned to form the patterned metal-containing photoresist and an optional etching step 809 during which the metal-free underlayer is etched using the patterned metal-containing photoresist with selectively deposited material as an etch mask.

Example embodiments of the invention are summarized here. Other embodiments can also be understood from the entirety of the specification as well as the claims filed herein.

Example 1. A method comprising: treating metal-containing mask surfaces and exposed surfaces of a metal-free underlayer with a promoter to form functionalized mask surfaces, the promoter being configured to selectively functionalize the metal-containing mask surfaces to form the functionalized mask surfaces, and promote selective deposition of a material on the functionalized mask surfaces; and treating the functionalized mask surfaces and the exposed surfaces of the metal-free underlayer with a precursor to selectively deposit the material on the functionalized mask surfaces.

Example 2. The method of example 1, wherein the metal-containing mask surfaces are formed from a patterned metal-oxide photoresist, wherein the promoter is a ligand configured to adsorb at metal sites of the patterned metal-oxide photoresist, and wherein the ligand comprises a functional group configured to interact with the precursor to promote the selective deposition of the material.

Example 3. The method of example 2, wherein the ligand comprises an acetylacetone species or a crown ether, wherein the patterned metal-oxide photoresist comprises tin oxide, and wherein the material is a silicon-based material or a carbon-based material.

Example 4. The method of one of examples 1 to 3, wherein the precursor comprises a halogen, and wherein the promoter also comprises the halogen.

Example 5. The method of one of examples 1 to 3, wherein the precursor comprises carbon, and wherein the promoter comprises an aliphatic group.

Example 6. The method of one of examples 1 to 5, wherein the promoter is a chelating molecule configured to form multiple bonds with a single metal atom.

Example 7. A method comprising: adsorbing a ligand at metal sites of a patterned metal-containing photoresist to form functionalized photoresist surfaces comprising the ligand by exposing both the patterned metal-containing photoresist and a metal-free underlayer to the ligand; and selectively depositing a material on the functionalized photoresist surfaces by exposing the functionalized photoresist surfaces and the metal-free underlayer to a precursor.

Example 8. The method of example 7, wherein the ligand comprises a functional group and a metal-bonding group comprising oxygen or nitrogen, the functional group being configured to interact with the precursor to promote selective deposition of the material on the functionalized photoresist surfaces.

Example 9. The method of example 8, wherein the functional group comprises fluorine, wherein the precursor also comprises fluorine, and wherein the material is a silicon-based material.

Example 10. The method of example 9, wherein the ligand is hexafluoroacetylacetone (HFAC), wherein the functional group is a trifluoromethyl group, and wherein the precursor is tetrafluorosilane.

Example 11. The method of example 8, wherein the functional group comprises and an aliphatic group, wherein the precursor comprises carbon, and wherein the material is a carbon-based material.

Example 12. The method of one of examples 7 to 11, wherein the ligand is a chelating molecule.

Example 13. The method of example 12, wherein the chelating molecule comprises an acetylacetone species or a crown ether.

Example 14. The method of one of examples 7 to 13, wherein the patterned metal-containing photoresist is a metal-oxide resist.

Example 15. The method of example 14, wherein the metal-oxide resist comprises tin oxide.

Example 16. A system comprising: a process chamber; a substrate support disposed in the process chamber and configured to support a substrate comprising metal-containing mask surfaces and exposed surfaces of a metal-free underlayer; a promoter source fluidically coupled to the process chamber and configured to provide a promoter through a first valve; a precursor source fluidically coupled to the process chamber and configured to provide a precursor through a second valve; and a controller operationally coupled to the first valve and the second valve, the controller comprising a processor and a non-transitory computer-readable medium storing a program including instructions that, when executed by the processor, perform a method comprising: treating the metal-containing mask surfaces and the exposed surfaces of the metal-free underlayer with the promoter to form functionalized mask surfaces, the promoter being configured to selectively functionalize the metal-containing mask surfaces to form the functionalized mask surfaces, and promote selective deposition of a material on the functionalized mask surfaces; and treating the functionalized mask surfaces and the exposed surfaces of the metal-free underlayer with the precursor to selectively deposit the material on the functionalized mask surfaces.

Example 17. The system of example 16, wherein the system is a plasma system, and wherein the process chamber is a plasma deposition chamber.

Example 18. The system of example 17, wherein the plasma system is a plasma etching system configured to perform the method in situ during an etching process.

Example 19. The system of one of examples 16 to 18, wherein the precursor comprises a halogen, and wherein the promoter also comprises the halogen.

Example 20. The system of one of examples 16 to 19, wherein the precursor comprises carbon, and wherein the promoter comprises an aliphatic group.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

1. A method comprising:
treating metal-containing mask surfaces and exposed surfaces of a metal-free underlayer with a promoter to form functionalized mask surfaces, the promoter being configured to
selectively functionalize the metal-containing mask surfaces to form the functionalized mask surfaces, and
promote selective deposition of a material on the functionalized mask surfaces; and
treating the functionalized mask surfaces and the exposed surfaces of the metal-free underlayer with a precursor to selectively deposit the material on the functionalized mask surfaces.

2. The method of claim 1,
wherein the metal-containing mask surfaces are formed from a patterned metal-oxide photoresist,
wherein the promoter is a ligand configured to adsorb at metal sites of the patterned metal-oxide photoresist, and
wherein the ligand comprises a functional group configured to interact with the precursor to promote the selective deposition of the material.

3. The method of claim 2,
wherein the ligand comprises an acetylacetone species or a crown ether,
wherein the patterned metal-oxide photoresist comprises tin oxide, and
wherein the material is a silicon-based material or a carbon-based material.

4. The method of claim 1, wherein the precursor comprises a halogen, and wherein the promoter also comprises the halogen.

5. The method of claim 1, wherein the precursor comprises carbon, and wherein the promoter comprises an aliphatic group.

6. The method of claim 1, wherein the promoter is a chelating molecule configured to form multiple bonds with a single metal atom.

7. A method comprising:
adsorbing a ligand at metal sites of a patterned metal-containing photoresist to form functionalized photoresist surfaces comprising the ligand by exposing both the patterned metal-containing photoresist and a metal-free underlayer to the ligand; and
selectively depositing a material on the functionalized photoresist surfaces by exposing the functionalized photoresist surfaces and the metal-free underlayer to a precursor.

8. The method of claim 7, wherein the ligand comprises a functional group and a metal-bonding group comprising oxygen or nitrogen, the functional group being configured to interact with the precursor to promote selective deposition of the material on the functionalized photoresist surfaces.

9. The method of claim 8,
wherein the functional group comprises fluorine,
wherein the precursor also comprises fluorine, and
wherein the material is a silicon-based material.

10. The method of claim 9,
wherein the ligand is hexafluoroacetylacetone (HFAC),
wherein the functional group is a trifluoromethyl group, and
wherein the precursor is tetrafluorosilane.

11. The method of claim 8,
wherein the functional group comprises an aliphatic group,
wherein the precursor comprises carbon, and
wherein the material is a carbon-based material.

12. The method of claim 7, wherein the ligand is a chelating molecule.

13. The method of claim 12, wherein the chelating molecule comprises an acetylacetone species or a crown ether.

14. The method of claim 7, wherein the patterned metal-containing photoresist is a metal-oxide resist.

15. The method of claim 14, wherein the metal-oxide resist comprises tin oxide.

16. A system comprising:
a process chamber;
a substrate support disposed in the process chamber and configured to support a substrate comprising metal-containing mask surfaces and exposed surfaces of a metal-free underlayer;
a promoter source fluidically coupled to the process chamber and configured to provide a promoter through a first valve;
a precursor source fluidically coupled to the process chamber and configured to provide a precursor through a second valve; and
a controller operationally coupled to the first valve and the second valve, the controller comprising a processor and a non-transitory computer-readable medium storing a program including instructions that, when executed by the processor, perform a method comprising:
treating the metal-containing mask surfaces and the exposed surfaces of the metal-free underlayer with the promoter to form functionalized mask surfaces, the promoter being configured to
selectively functionalize the metal-containing mask surfaces to form the functionalized mask surfaces, and
promote selective deposition of a material on the functionalized mask surfaces; and
treating the functionalized mask surfaces and the exposed surfaces of the metal-free underlayer with the precursor to selectively deposit the material on the functionalized mask surfaces.

17. The system of claim 16, wherein the system is a plasma system, and wherein the process chamber is a plasma deposition chamber.

18. The system of claim 17, wherein the plasma system is a plasma etching system configured to perform the method in situ during an etching process.

19. The system of claim 16, wherein the precursor comprises a halogen, and wherein the promoter also comprises the halogen.

20. The system of claim 16, wherein the precursor comprises carbon, and wherein the promoter comprises an aliphatic group.
